(19) United States
(12) Patent Application Publication
(10) Pub. No.: US 2021/0213723 A1
(43) Pub. Date: Jul. 15, 2021

(54) LAMINATION DEVICE FOR A PHOTOVOLTAIC MODULE

(71) Applicant: Miasole Equipment Integration (Fujian) Co., Ltd., Fujian (CN)

(72) Inventors: Jun TAN, Fujian (CN); Wenbiao YAO, Fujian (CN); Qizheng JIANG, Fujian (CN); Jianghui HUANG, Fujian (CN); Bin ZHANG, Fujian (CN); Xiaoning RU, Fujian (CN); Hongxia SUN, Fujian (CN)

(21) Appl. No.: 16/089,543

(22) PCT Filed: Sep. 10, 2018
(86) PCT No.: PCT/CN2018/104828

§ 371 Date: Sep. 28, 2018

(30) Foreign Application Priority Data
Dec. 18, 2017 (CN) 201721770562.X

(51) Int. Cl. B32B 37/10; H01L 31/048; H01L 31/18; B32B 41/00

(52) U.S. Cl. CPC B32B 37/1018; H01L 31/048; B32B 2457/12; B32B 37/1036; B32B 41/00; H01L 31/18

(57) ABSTRACT

Provided is a lamination device for a photovoltaic module. The lamination device includes: a conveyor, a vacuum adsorption structure, a vacuum break structure and a lamination wheel. The vacuum adsorption structure is disposed on a first end of the conveyor, and configured to adsorb the photovoltaic module to the conveyor. The vacuum break structure is disposed on a second end of the conveyor, and configured to separate the photovoltaic module from the conveyor. The lamination wheel is disposed above the conveyor. A lamination gap is provided between the lamination wheel and the conveyor. A projection of the lamination wheel on the conveyor is between a projection of the vacuum adsorption structure on the conveyor and a projection of the vacuum break structure on the conveyor.

This application claims priority to Chinese patent application No. 201721770562.X filed on Dec. 18, 2017, entitled “Lamination Device For a Photovoltaic Module”, the disclosure of which is incorporated herein by reference in its entirety.

### TECHNICAL FIELD

The present disclosure relates to the field of solar technology, and in particular to a lamination device for a photovoltaic module.

### BACKGROUND

Generally, in the solar cell manufacturing process, in order to obtain a better current collecting effect, a metal busbar is usually formed on the light incident surface. At present, a grid electrode of the metal busbar is laminated on the light incident surface before the photovoltaic module 1 and the stainless steel substrate are packaged. In the process of manufacturing the grid electrode of the metal busbar, as shown in FIG. 1, firstly, first flexible material 2 is laminated with a conductive wire 4, and then second flexible material 3 is laminated with the laminated first flexible material 2 and the conductive wire 4 to complete the manufacture of the photovoltaic module 1.

In the process of manufacturing photovoltaic module described above, the positions of the first flexible material 2 and the second flexible material 3 with respect to the conductive wire 4 cannot be changed during the lamination process. In related arts, firstly the positions of raw materials are controlled with a rectification device, and then the raw materials with predetermined positions are laminated through a lamination device. As shown in FIG. 2, the lamination device includes an upper lamination wheel 5 and a lower lamination wheel 6, and a gap is formed between the upper lamination wheel 5 and the lower lamination wheel 6. The left side of the upper lamination wheel 5 and the lower lamination wheel 6 is provided with a left conductive copper roller 7, and the right side of the upper lamination wheel 5 and the lower lamination wheel 6 is provided with a right conductive copper roller 8. In the lamination process, the raw materials with predetermined positions are sent, by the left conductive copper roller 7, into the gap between the upper lamination wheel 5 and the lower lamination wheel 6 for being laminated, and then are outputted from the lamination device by the right conductive copper roller 8 However, in the lamination process, the position deviation of the second flexible material 3 or defects such as folds still occur, and the product loss rate is large.

### SUMMARY

In order to solve the above problem, the present disclosure provides a lamination device for a photovoltaic module. In the process of manufacturing the grid electrode of the metal busbar, after the conductive wire and the first flexible material layer are laminated into an integral structure, the positon deviation of the second flexible material with respect to the integral structure is avoided, thereby reducing folds of the photovoltaic module and the loss rate of photovoltaic module.

The lamination device for a photovoltaic module includes a conveyor, a vacuum adsorption structure, a vacuum break structure and a lamination wheel. The vacuum adsorption structure is disposed on a first end of the conveyor and configured to adsorb the photovoltaic module to the conveyor. The vacuum break structure is disposed on a second end of the conveyor and configured to separate the photovoltaic module from the conveyor. The lamination wheel is disposed above the conveyor. A lamination gap is provided between the lamination wheel and the conveyor. A projection of the lamination wheel on the conveyor is between a projection of the vacuum adsorption structure on the conveyor and a projection of the vacuum break structure on the conveyor.

In the above lamination device for a photovoltaic module, alternatively, the conveyor includes: a conveyor belt, configured to convey the photovoltaic module, wherein the conveyor belt comprises through holes; and a first driving assembly, configured to drive the conveyor belt to operate.

In the above lamination device for a photovoltaic module, alternatively, the vacuum adsorption structure includes: a vacuum chamber, which is disposed below a conveying surface of the conveyor belt and has a first opening area, and a vacuum pumping mechanism, which is disposed below the conveying surface of the conveyor belt. A suction port of the vacuum pumping mechanism is communicated with the vacuum chamber. The vacuum chamber, a part of the conveyor belt corresponding to the first opening area and the photovoltaic module form a sealed space.

In the above lamination device for a photovoltaic module, alternatively, the vacuum break structure includes: an inflatable chamber, which is disposed below a conveying surface of the conveyor belt and has a second opening area, and a vacuum break mechanism, which is disposed below the conveying surface of the conveyor belt. An air outlet of the vacuum break mechanism is communicated with the inflatable chamber. The inflatable chamber, a part of the conveyor belt corresponding to the second opening area and the photovoltaic module form a sealed space.

The above lamination device for a photovoltaic module, alternatively, further includes a second driving assembly, disposed above a conveying surface of the conveyor belt and configured to drive the lamination wheel to rotate.

In the above lamination device for a photovoltaic module, alternatively, the first driving assembly includes a servo motor, and the second driving assembly includes a stepping motor.

The above lamination device for a photovoltaic module, alternatively, further includes a first guiding wheel disposed in a conveying direction of the conveyor. The first guiding wheel is located on a side of the conveyor where the vacuum adsorption structure is disposed, and a top tangent plane of the first guiding wheel is in a same plane as a conveying surface of the conveyor belt.

The above lamination device for a photovoltaic module, alternatively, further includes a second guiding wheel, disposed in a conveying direction of the conveyor. The second guiding wheel is located on a side of the conveyor where the vacuum break structure is disposed, and a top tangent plane of the second guiding wheel is in a same plane as a conveying surface of the conveyor belt.

The above lamination device for a photovoltaic module, alternatively, further includes a third driving assembly, configured to drive the lamination wheel to move along a direction perpendicular to a conveying surface of the conveyor to adjust a width of the lamination gap.

In the above lamination device for a photovoltaic module, alternatively, the third driving assembly includes a cylinder.

In the lamination device for a photovoltaic module provided in the present disclosure, the photovoltaic module to be laminated is firstly fixed in a vacuum adsorption manner, and then is laminated, so the position of the photovoltaic module to be laminated is fixed, and the positions of the raw materials are not changed, thereby reducing folds of the photovoltaic module and the loss rate of photovoltaic module.

### BRIEF DESCRIPTION OF DRAWINGS

FIG. 1 is a structure diagram of a photovoltaic module;

FIG. 2 is a structure diagram of a lamination device in related arts;

FIG. 3 is a structure diagram of a lamination device for a photovoltaic module according to an embodiment of the present disclosure;

FIG. 4 is top view of a lamination device for a photovoltaic module according to an embodiment of the present disclosure;

FIG. 5 is side view of a lamination device for a photovoltaic module according to an embodiment of the present disclosure; and

FIG. 6 is a structure diagram of another lamination device for a photovoltaic module according to an embodiment of the present disclosure.

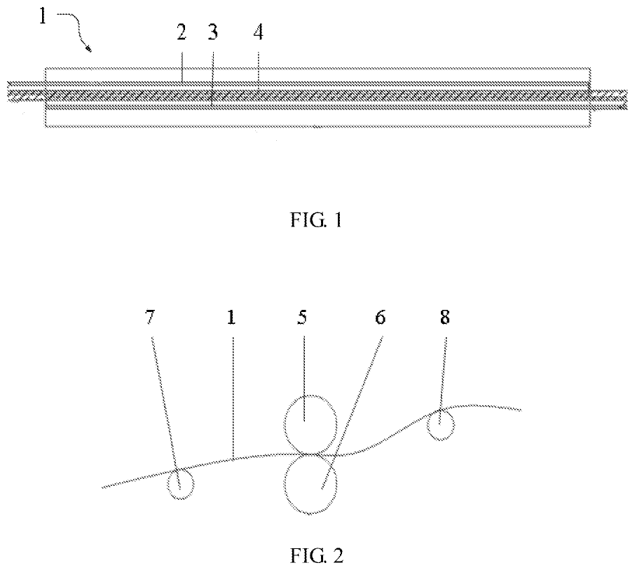

### LIST OF REFERENCE NUMERALS IN THE DRAWINGS

1: photovoltaic module; 2: first flexible material; 3: second flexible material;
4: conductive thread; 5: upper lamination wheel; 6: lower lamination wheel;
7: left conductive copper roller; 8: right conductive copper roller; 10: conveyor;
11: vacuum adsorption structure; 12: vacuum break structure;
20: lamination wheel; 30: first guiding wheel; 40: second guiding wheel;
50: first driving assembly; 60: second driving assembly; 70: photovoltaic module;
80: support; 13: conveyor belt; 131: through-hole; 111: vacuum chamber;
112: part of the conveyor belt corresponding to the opening of the vacuum chamber;
113: vacuum pumping mechanism; 114: connection holes for vacuum generator;
121: inflatable chamber;
122: part of the conveyor belt corresponding to the opening of the vacuum chamber;
123: vacuum break mechanism; 124: air tube connector.

### DETAILED DESCRIPTION

The following describes the embodiments of the present disclosure, examples of the embodiments are shown in drawings, and the same or similar reference numerals throughout represent the same or similar elements or elements with the same or similar functions. The embodiments described below by referring to the drawings are exemplary.

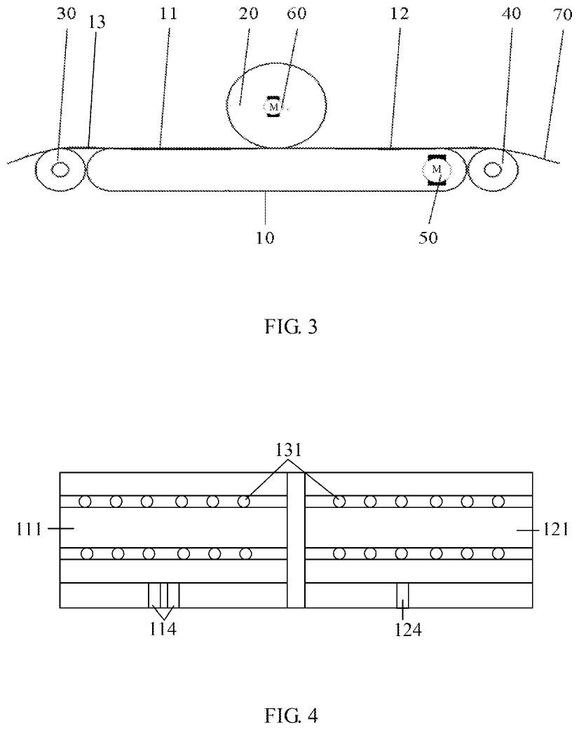

As shown in FIG. 3, a lamination device for a photovoltaic module provided in this embodiment includes a conveyor 10 and a lamination wheel 20.

A vacuum adsorption structure 11 is disposed on a first end of the conveyor 10, and the vacuum adsorption structure 11 is configured to adsorb the photovoltaic module to the conveyor 10. A vacuum break structure 12 is disposed on a second end of the conveyor 10, and the vacuum break structure 12 is configured to separate the photovoltaic module from the conveyor 10. The lamination wheel 20 is disposed above the conveyor 10, a lamination gap is provided between the lamination wheel 20 and the conveyor 10, and a width of the lamination gap is adjustable. A projection of the lamination wheel 20 on a conveying surface of the conveyor 10 is between a projection of the vacuum adsorption structure 11 on the conveying surface of the conveyor 10 and a projection of the vacuum break structure 12 on the conveying surface of the conveyor 10.

The first end of the conveyor 10 is an end located at a side of the lamination device for the photovoltaic module, and the second end of the conveyor 10 is an end located at the other side of the lamination device for the photovoltaic module. The conveying surface of the conveyor 10 is a surface facing the lamination wheel 20 and configured to convey the photovoltaic module 70. An area of the conveyor 10 corresponding to the vacuum adsorption structure 11 is a vacuum adsorption area, and an area of the conveyor 10 corresponding to the vacuum break structure 20 is a vacuum break area.

In one or more embodiments, as shown in FIG. 3 and FIG. 4, the conveyor 10 includes a conveyor belt 13, which is configured to convey the photovoltaic module 70 and t includes through holes 131, and a first driving assembly 50, configured to drive the conveyor belt 13 to operate.

In the photovoltaic module 70 to be laminated, the first flexible material and the conductive wire have been made into one piece. The second flexible material is laminated with the first flexible material and the conductive wires which are made into one piece using the lamination device for the photovoltaic module. In the lamination process, the photovoltaic module 70 to be laminated is placed on the conveyor 10 from the end where the vacuum adsorption area of the conveyor 10 is located. Then, the conveyor 10 starts to operate, and the photovoltaic module 70 to be laminated is adsorbed on the conveyor belt 13 in the vacuum adsorption area, so as to fix the position of the second flexible material with respect to the first flexible material and the conductive wire which have been made into one piece. When the second flexible material, the first flexible material and the conductive wire pass the lamination gap between the lamination wheel 20 and the conveyor 10, the lamination wheel 20 cooperates with the conveyor 10 to complete the lamination of photovoltaic module 70. Then, the laminated photovoltaic module 70 enters the vacuum break area of the conveyor 10, the photovoltaic module 70 is separated from the conveyor belt 13 and transferred out of the conveyor 10, and the lamination is completed.

For the lamination device for the photovoltaic module in related arts, because the position of the second flexible material with respect to the first flexible material and the conductive wire which have been made into one piece is not fixed, there is position deviation in the lamination process. The lamination device for the photovoltaic module provided in this embodiment uses vacuum adsorption to adsorb the photovoltaic module 70 to be laminated, so that the position of the photovoltaic module 70 to be laminated is fixed, and the position of the second flexible material will not shift in the lamination process. The folding phenomenon of the photovoltaic module 70 and the loss rate of the photovoltaic module 70 are reduced.

In one or more embodiments, the vacuum adsorption structure includes a vacuum chamber and a vacuum pumping mechanism. The vacuum chamber is disposed below the conveying surface of the conveyor belt, and includes a first opening area. The vacuum pumping mechanism is disposed below the conveying surface of the conveyor belt, and a suction port of the vacuum pumping mechanism is communicated with the vacuum chamber. The vacuum chamber, a part of the conveyor belt corresponding to the first opening area and the photovoltaic module form a sealed space.

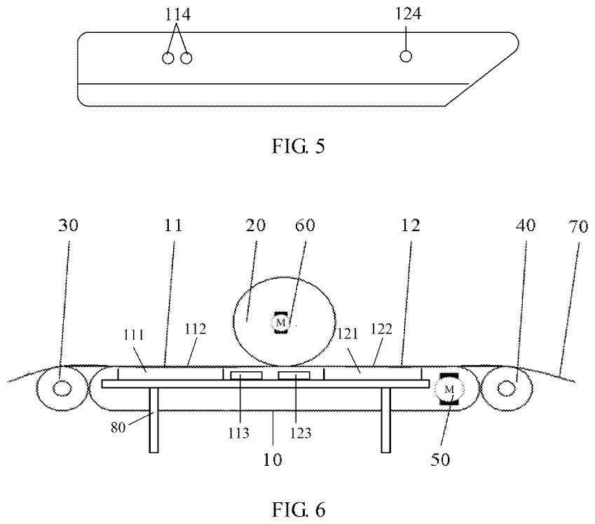

FIG. 4 is top view of the lamination device for the photovoltaic module according to an embodiment of the present disclosure, FIG. 5 is side view of the lamination device for the photovoltaic module according to an embodiment of the present disclosure, and FIG. 6 is a structure diagram of the lamination device for the photovoltaic module according to an embodiment of the present disclosure. As shown in FIG. 4-FIG. 6, the vacuum adsorption structure 11 includes a vacuum chamber 111, a part 112 of the conveyor belt corresponding to the opening of the vacuum chamber 112 which is a part of the conveyor belt corresponding to the first opening area of the vacuum chamber, and a vacuum pumping mechanism 113. The part 112 of the conveyor belt corresponding to the opening of the vacuum chamber is tightly attached with the vacuum chamber 111. The suction port of the vacuum pumping mechanism 113 is communicated with the vacuum chamber 111 via connection holes 114 for a vacuum generator. The vacuum chamber 111 is a groove structure with an opening, that is the above mentioned first opening area, and the opening is opposite to the conveyor belt 13. The conveyor belt 13 is provided with multiple through holes 131. When the photovoltaic module 70 to be laminated is placed on the part of the conveyor belt corresponding to the opening of the vacuum chamber 112, the vacuum pumping mechanism 113 is started and the vacuum chamber 111 is evacuated, air between the photovoltaic module 70 to be laminated and the conveyor 10 is pumped out through the through holes 131, such that the photovoltaic module 70 to be laminated is absorbed on the conveyor belt 13. In one or more embodiments, the vacuum pumping mechanism 113 is a vacuum pump.

In one or more embodiments, the vacuum break structure includes an inflatable chamber and a vacuum break mechanism. The inflatable chamber is disposed below the conveying surface of the conveyor belt, and the inflatable chamber includes a second opening area. The vacuum break mechanism is disposed below the conveying surface of the conveyor belt, and an air outlet of the vacuum break mechanism is communicated with the inflatable chamber. The inflatable chamber, a part of the conveyor belt corresponding to the second opening area and the photovoltaic module form a sealed space.

As shown in FIG. 4-FIG. 6, the vacuum break structure 12 includes the inflatable chamber 121, a part 122 of the conveyor belt corresponding to the opening of the inflatable chamber and the vacuum break mechanism 123. The part 122 of the conveyor belt corresponding to the opening of the inflatable chamber 121 is a part of the conveyor belt corresponding to the second opening area. The part 122 of the conveyor belt corresponding to the opening of the inflatable chamber is tightly attached with the inflatable chamber 121. An air outlet of the vacuum break mechanism 123 is communicated with the inflatable chamber 121 via an air tube connector 124. The inflatable chamber 121 is a groove structure with an opening, that is the second opening area, and the opening is opposite to the conveyor belt. After the laminated photovoltaic module 70 reaches the part 122 of the conveyor belt corresponding to the opening of the inflatable chamber, the inflatable chamber 121 is filled with air by the vacuum break mechanism through the air tube connector 124, such that the through-holes 131 between the photovoltaic module 70 and the conveyor belt are filled with air and the photovoltaic module 70 is in a free state. In one or more embodiments, the vacuum break mechanism includes an air compressor pump, the air outlet of the air compressor pump is connected to an air inlet of the inflatable chamber 121, so as to fill the inflatable chamber 121 with compressed air and break the vacuum adsorption between the photovoltaic module 70 and the conveyor belt 13.

As shown in FIG. 6, a support 80 is disposed below the conveyor 10, and the support 80 is configured to support the conveyor 10. The vacuum chamber 111, the inflatable chamber 121, the vacuum pumping mechanism 113 and the vacuum break mechanism 123 are all disposed on the support 80. As shown in FIG. 3 and FIG. 6, the vacuum chamber 111 and the vacuum pumping mechanism 113 are disposed on the support 80 below the vacuum adsorption area, the inflatable chamber 121 and the vacuum break mechanism 123 are disposed on the sent 80 below the vacuum break area.

In one or more embodiments, the lamination device for the photovoltaic module further includes a first guiding wheel 30, and the first guiding wheel 30 is disposed on a conveying direction of the conveyor 10. The first guiding wheel 30 is located on a side of the conveyor 10 where the vacuum adsorption structure 11 is disposed, and a top tangent plane of the first guiding wheel 30 is in the same plane as the conveying surface of the conveyor 10. Before the photovoltaic module 70 to be laminated enters the conveyor 10, the photovoltaic module 70 needs to go through the first guiding wheel 30, so that the photovoltaic module 70 to be laminated is guided into the vacuum adsorption area. The top tangent plane of the first guiding wheel 30 is in the same plane as the conveying surface of the conveyor, thereby avoiding the position deviation of the second flexible material layer in the process of transferring the photovoltaic module 70 to the conveyor 10.

In one or more embodiments, the lamination device for the photovoltaic module further includes a second guiding wheel 40, and the second guiding wheel 40 is disposed on the conveying direction of the conveyor 10. The second guiding wheel is located on a side of the conveyor 10 where the vacuum break structure 12 is disposed, and a top tangent plane of the second guiding wheel 40 is in the same plane as the conveying surface of the conveyor 10. After the photovoltaic module 70 is laminated between the lamination wheel 20 and the conveyor 10, the photovoltaic module 70 is transferred to the vacuum break area of the conveyor 10, and then is transferred to the second guiding wheel 40 and leaves the lamination device for the photovoltaic module from the second guiding wheel 40. The top tangent plane of the second guiding wheel 40 is in the same plane as the conveying surface of the conveyor 10, which is conducive to making the laminated photovoltaic module 70 in a right configuration, and assists in crimp.

In one or more embodiments, the conveyor 10 is driven by a first driving assembly 50, and the lamination wheel 20 is driven by a second driving assembly 60. In one or more embodiments, the first driving assembly 50 is a servo motor, and the second driving assembly 60 is a stepping motor.

When the lamination device for the photovoltaic module is not in use, the lamination wheel 20 may be kept away from the conveyor 10. Therefore, the lamination device for the photovoltaic module provided in this embodiment further includes a third driving assembly, and the third driving assembly is configured to drive the lamination wheel 20 to move along a direction perpendicular to the conveying surface of the conveyor 10 to adjust the lamination gap. In one or more embodiments, the third driving assembly includes a cylinder. In the lamination process, the cylinder is started and drives the lamination wheel 20 to move downward, and the lamination gap is reduced, so that it is easy to laminate the photovoltaic module assembly 70. After the lamination process is completed, the cylinder drives the lamination wheel 20 upward to move away from the conveyor 10, and the lamination gap is increased, thus facilitating the photovoltaic module 70 to leave.

The work process of the lamination device for the photovoltaic module provided in this embodiment is described hereinafter.

The third driving assembly is started to drive the lamination wheel 20 move downward to match the conveyor 10. The photovoltaic module 70 to be laminated is transferred into the vacuum adsorption area of the conveyor 10 through the first guiding wheel 30, and the photovoltaic module 70 to be laminated is fixed by adsorption. The first driving assembly 50 is started to drive the conveyor belt 13 to operate, and the photovoltaic module 70 to be laminated is conveyed to right with the conveyor belt 13. The photovoltaic module 70 to be laminated is laminated between the lamination wheel 20 and the conveyor 10. The photovoltaic module 70 to be laminated is transferred to right to the vacuum break area of the conveyor 10, and then is curled, and the lamination is finished.

Any of the embodiments in the present disclosure may be combined arbitrarily to form multiple groups of embodiments that include different characteristics. As the embodiments described above have detailed the characteristics of different embodiments, and are not enumerated herein.

Embodiments in accordance with drawings in the present disclosure illustrate the structure, characteristics and functions of the present disclosure, the above description are merely exemplary embodiments of the present disclosure, but the disclosure does not limit the scope of the implementations as shown in the drawings. All equivalent embodiments with equivalent changes modified or changed according to the concept of the present disclosure are within the protection scope of the present disclosure, when they are not beyond the scope of the description and drawings.

1. A lamination device for a photovoltaic module, comprising:
a conveyor;
a vacuum adsorption structure, disposed on a first end of the conveyor, and configured to adsorb the photovoltaic module to the conveyor;
a vacuum break structure, disposed on a second end of the conveyor, and configured to separate the photovoltaic module from the conveyor; and
a lamination wheel, disposed above the conveyor, wherein a lamination gap is provided between the lamination wheel and the conveyor, and a projection of the lamination wheel on the conveyor is between a projection of the vacuum adsorption structure on the conveyor and a projection of the vacuum break structure on the conveyor.

2. The lamination device for the photovoltaic module of claim 1, wherein the conveyor comprises:
a conveyor belt, configured to convey the photovoltaic module, wherein the conveyor belt comprises through holes; and
a first driving assembly, configured to drive the conveyor belt to operate.

3. The lamination device for the photovoltaic module of claim 2, wherein the vacuum adsorption structure comprises:
a vacuum chamber, disposed below a conveying surface of the conveyor belt, wherein the vacuum chamber comprises a first opening area; and
a vacuum pumping mechanism, disposed below the conveying surface of the conveyor belt, wherein a suction port of the vacuum pumping mechanism is communicated with the vacuum chamber,
wherein the vacuum chamber, a part of the conveyor belt corresponding to the first opening area and the photovoltaic module form a sealed space.

4. The lamination device for the photovoltaic module of claim 2, wherein the vacuum break structure comprises:
an inflatable chamber, disposed below a conveying surface of the conveyor belt, wherein the inflatable chamber comprises a second opening area; and
a vacuum break mechanism, disposed below the conveying surface of the conveyor belt, wherein an air outlet of the vacuum break mechanism is communicated with the inflatable chamber,
wherein the inflatable chamber, a part of the conveyor belt corresponding to the second opening area and the photovoltaic module form a sealed space.

5. The lamination device for the photovoltaic module of claim 2, further comprising:
a second driving assembly, disposed above a conveying surface of the conveyor belt and configured to drive the lamination wheel to rotate.

6. The lamination device for the photovoltaic module of claim 5, wherein the first driving assembly comprises a servo motor, and the second driving assembly comprises a stepping motor.

7. The lamination device for the photovoltaic module of claim 2, further comprising: a first guiding wheel, disposed in a conveying direction of the conveyor, wherein the first guiding wheel is located on a side of the conveyor where the vacuum adsorption structure is disposed, and a top tangent plane of the first guiding wheel is in a same plane as a conveying surface of the conveyor belt.

8. The lamination device for the photovoltaic module of claim 2, further comprising: a second guiding wheel, disposed in a conveying direction of the conveyor, wherein the second guiding wheel is located on a side of the conveyor where the vacuum break structure is disposed, and a top tangent plane of the second guiding wheel is in a same plane as a conveying surface of the conveyor belt.

9. The lamination device for the photovoltaic module of claim 1, further comprising: a third driving assembly, configured to drive the lamination wheel to move along a direction perpendicular to a conveying surface of the conveyor to adjust a width of the lamination gap.

10. The lamination device for the photovoltaic module of claim 9, wherein the third driving assembly comprises a cylinder.

11. The lamination device for the photovoltaic module of claim 3, wherein the vacuum break structure comprises:
an inflatable chamber, disposed below a conveying surface of the conveyor belt, wherein the inflatable chamber comprises a second opening area; and
a vacuum break mechanism, disposed below the conveying surface of the conveyor belt, wherein an air outlet of the vacuum break mechanism is communicated with the inflatable chamber,
wherein the inflatable chamber, a part of the conveyor belt corresponding to the second opening area and the photovoltaic module form a sealed space.

12. The lamination device for the photovoltaic module of claim 2, further comprising: a third driving assembly, configured to drive the lamination wheel to move along a direction perpendicular to a conveying surface of the conveyor to adjust a width of the lamination gap.

13. The lamination device for the photovoltaic module of claim 3, further comprising: a third driving assembly, configured to drive the lamination wheel to move along a direction perpendicular to a conveying surface of the conveyor to adjust a width of the lamination gap.

14. The lamination device for the photovoltaic module of claim 4, further comprising: a third driving assembly, configured to drive the lamination wheel to move along a direction perpendicular to a conveying surface of the conveyor to adjust a width of the lamination gap.

15. The lamination device for the photovoltaic module of claim 5, further comprising: a third driving assembly, configured to drive the lamination wheel to move along a direction perpendicular to a conveying surface of the conveyor to adjust a width of the lamination gap.

16. The lamination device for the photovoltaic module of claim 6, further comprising: a third driving assembly, configured to drive the lamination wheel to move along a direction perpendicular to a conveying surface of the conveyor to adjust a width of the lamination gap.

16. The lamination device for the photovoltaic module of claim 7, further comprising: a third driving assembly, configured to drive the lamination wheel to move along a direction perpendicular to a conveying surface of the conveyor to adjust a width of the lamination gap.

17. The lamination device for the photovoltaic module of claim 8, further comprising: a third driving assembly, configured to drive the lamination wheel to move along a direction perpendicular to a conveying surface of the conveyor to adjust a width of the lamination gap.

18. The lamination device for the photovoltaic module of claim 11, further comprising: a third driving assembly, configured to drive the lamination wheel to move along a direction perpendicular to a conveying surface of the conveyor to adjust a width of the lamination gap.
